(19) United States
(12) Patent Application Publication
(10) Pub. No.: US 2018/0062622 A1
(43) Pub. Date: Mar. 1, 2018

(54) BINARY-WEIGHTED ATTENUATOR HAVING COMPENSATION CIRCUIT

(71) Applicant: SKYWORKS SOLUTIONS, INC., Woburn, MA (US)

(72) Inventors: Yan YAN, Irvine, CA (US); Junhyung LEE, Irvine, CA (US)

(21) Appl. No.: 15/687,476

(22) Filed: Aug. 26, 2017

Related U.S. Application Data
(60) Provisional application No. 62/381,376, filed on Aug. 30, 2016.

(51) Int. Cl. H03H 11/24

(52) U.S. Cl. CPC H03H 11/245; H03F 3/213

(57) ABSTRACT

Binary-weighted attenuator having compensation circuit. In some embodiments, a radio-frequency (RF) attenuator circuit can include a plurality of attenuation blocks arranged in series between an input node and an output node, with each of the plurality of attenuation blocks including a bypass path. The RF attenuator circuit can further include a phase compensation circuit implemented for each of at least some of the attenuation blocks having the respective bypass paths. The phase compensation circuit can be configured to compensate for an off-capacitance effect associated with the corresponding bypass path.

### CROSS-REFERENCE TO RELATED APPLICATION(S)

This application claims priority to U.S. Provisional Application No. 62/381,376 filed Aug. 30, 2016, entitled BINARY-WEIGHTED ATTENUATOR HAVING COMPENSATION CIRCUIT, the disclosure of which is hereby expressly incorporated by reference herein in its respective entirety.

### BACKGROUND

### Field

The present disclosure relates to attenuators for electronic applications.

### Description of the Related Art

In electronic applications such as radio-frequency (RF) applications, it is sometimes desirable to amplify or attenuate a signal. For example, a to-be-transmitted signal can be amplified by a power amplifier, and a received signal can be amplified by a low-noise amplifier. In another example, one or more attenuators can be implemented along either or both of the foregoing transmit and receive paths as needed or desired to attenuate the respective signal(s).

### SUMMARY

In accordance with some implementations, the present disclosure relates to a radio-frequency attenuator circuit that includes a plurality of attenuation blocks arranged in series between an input node and an output node, with each of the plurality of attenuation blocks including a bypass path. The attenuator circuit further includes a phase compensation circuit implemented for each of at least some of the attenuation blocks having the respective bypass paths. The phase compensation circuit is configured to compensate for an off-capacitance effect associated with the corresponding bypass path.

In some embodiments, the attenuation blocks can have binary-weighted attenuation values. The binary-weighted attenuation values can include N values, with an i-th value being A2ⁱ⁻¹, where A is a step attenuation value and i is a positive integer from 1 to N. The step attenuation value A can be, for example, approximately 1 dB. The quantity N can include, for example, 2, 3, 4, 5, 6, 7 or 8.

In some embodiments, at least one of the attenuation blocks can be without a phase compensation circuit. The at least one attenuation block without the phase compensation circuit can include an attenuation block having a lowest attenuation value.

In some embodiments, at least one of the attenuation blocks can be configured as a pi-attenuator. The at least one attenuation block having the pi-attenuator can include an attenuation block having a highest attenuation value.

In some embodiments, the bypass path of the attenuation block having the pi-attenuator can include a bypass switching transistor configured to be on when the attenuation block is in a bypass mode and off when in an attenuation mode, such that the bypass switching transistor provides an off-capacitance when in the attenuation mode. The phase compensation circuit of the attenuation block having the pi-attenuator can include a phase compensation circuit configured to compensate for the off-capacitance when the attenuator block is in the attenuation mode. The pi-attenuator can include a resistance, a first shunt path implemented between one end of the resistance and a ground, and a second shunt path implemented between the other end of the resistance and the ground. Each of the first and second shunt paths can include a shunt resistance.

In some embodiments, the phase compensation circuit associated with the pi-attenuator can include a first compensation capacitance arranged to be electrically parallel with the first shunt resistance, and a second compensation capacitance arranged to be electrically parallel with the second shunt resistance. The off-capacitance of the bypass switching transistor can result in a phase lead change, and the phase compensation circuit can be configured to provide a phase lag change to compensate for the phase lead change. The first and second shunt resistances can have substantially the same value, and the first and second compensation capacitances have substantially the same value.

In some embodiments, the phase lead change can be by an amount calculated as

$$φ = {tan}^{- 1} ( ω {R}_{1} {C}_{off} ) - {tan}^{- 1} ( ω \frac{{R}_{1} {R}_{L}}{{R}_{1} + {R}_{L}} {C}_{off} ) ,$$

and the phase lag change can be by an amount calculated as

$$φ = - {tan}^{- 1} ( \frac{ω {R}_{1} {R}_{2}^{′} {C}_{c}}{{R}_{1} + {R}_{2}^{′}} ) ,$$

where ω is 2π times frequency, R_{L} is load impedance, R₁ is the resistance, C_{C} is the first local compensation capacitance, and R₂′ is an equivalent resistance of a parallel arrangement of the first shunt resistance and the load impedance. The value of the first compensation capacitance can be selected such that magnitude of the phase lag change is substantially the same as magnitude of the phase lead change. The value of the compensation capacitance can be selected such that a gain of the attenuation block is approximately flat over a selected frequency range.

In some embodiments, at least one of the attenuation blocks can be configured as a bridge-T-attenuator. The bypass path of the attenuation block having the bridge-T-attenuator can include a bypass switching transistor configured to be on when the attenuation block is in a bypass mode and off when in an attenuation mode, such that the bypass switching transistor provides an off-capacitance when in the attenuation mode. The phase compensation circuit of the attenuation block having the bridge-T-attenuator can include a phase compensation circuit configured to compensate for the off-capacitance when the attenuator block is in the attenuation mode.

In some embodiments, the bridge-T-attenuator can include two first resistances connected in series, a second resistance electrically parallel with the series combination of the two first resistances, and a shunt path implemented between a ground and a node between the two first resistances, the shunt path including a shunt resistance. The phase compensation circuit associated with the bridge-T-attenuator can include a compensation capacitance arranged to be electrically parallel with the shunt resistance.

In some embodiments, the off-capacitance of the bypass switching transistor can result in a phase lead change, and the phase compensation circuit can be configured to provide a phase lag change to compensate for the phase lead change. The phase lead change can be by an amount calculated as

$$φ = {tan}^{- 1} ( ω {R}_{2} {C}_{off} ) - {tan}^{- 1} ( \frac{ω {R}_{2} {C}_{off}}{1 + \frac{{R}_{2}}{{R}_{L}}} ) ,$$

and the phase lag change can be by an amount calculated as

$$φ = - {tan}^{- 1} ( \frac{ω {R}_{1} {R}_{3}^{′} {C}_{c}}{{R}_{1} + {R}_{3}^{′}} ) ,$$

where ω is 2π times frequency, R_{L} is load impedance, R₁ is the first resistance, R₂ is the second resistance, C_{C} is the compensation capacitance, and R₃′ is an equivalent resistance of a parallel arrangement of the shunt resistance and a series-combination of the first resistance and the load impedance. The value of the compensation capacitance can be selected such that magnitude of the phase lag change is substantially the same as magnitude of the phase lead change. The value of the compensation capacitance can be selected such that a gain of the attenuation block is approximately flat over a selected frequency range.

In some embodiments, the attenuator circuit can further include a global bypass path that includes a global bypass switching transistor configured to be on when in a global bypass mode and off when in a global attenuation mode, such that the global bypass switching transistor provides a global off-capacitance when in the global attenuation mode. In some embodiments, the attenuator circuit can further include a global phase compensation circuit configured to compensate for the global off-capacitance when the attenuator circuit is in the global attenuation mode. The global phase compensation circuit can include a first global compensation resistance and a second global compensation resistance arranged in series between the input node and the output node. The global phase compensation circuit can further include a global compensation capacitance implemented between a ground and a node between the first and second global compensation resistances. The global off-capacitance of the global bypass switching transistor can result in a phase lead change, and the global phase compensation circuit can be configured to provide a phase lag change to compensate for the phase lead change. The first and second global compensation resistances can have substantially the same value.

In some embodiments, the phase lead change can be by an amount calculated as

$$φ = {tan}^{- 1} ( 2 ω {R}_{G 1} {C}_{off} ) - {tan}^{- 1} ( \frac{2}{3} ω {R}_{G 1} {C}_{off} ) ,$$

and the phase lag change can be by an amount calculated as

$$φ = - {tan}^{- 1} ( \frac{2}{3} ω {R}_{G 1} {C}_{G} ) ,$$

where ω is 2π times frequency, R_{L} is load impedance, R_{G1} is the first global compensation resistance, and C_{G} is the global compensation capacitance. The values of the first global compensation resistance and the global compensation capacitance can be selected such that magnitude of the phase lag change is substantially the same as magnitude of the phase lead change. The value of the global compensation capacitance can be selected such that a global gain of the attenuator circuit is approximately flat over a selected frequency range.

In some teachings, the present disclosure relates to a semiconductor die having a radio-frequency circuit. The semiconductor die includes a semiconductor substrate, and an attenuator circuit implemented on the semiconductor substrate. The attenuator circuit includes a plurality of attenuation blocks arranged in series between an input node and an output node, with each of the plurality of attenuation blocks including a bypass path. The attenuator circuit further includes a phase compensation circuit implemented for each of at least some of the attenuation blocks having the respective bypass paths. The phase compensation circuit is configured to compensate for an off-capacitance effect associated with the corresponding bypass path.

According to some teachings, the present disclosure relates to a radio-frequency module that includes a packaging substrate configured to receive a plurality of components, and a radio-frequency attenuator circuit implemented on the packaging substrate. The attenuator circuit includes a plurality of attenuation blocks arranged in series between an input node and an output node, with each of the plurality of attenuation blocks including a bypass path. The attenuator circuit further includes a phase compensation circuit implemented for each of at least some of the attenuation blocks having the respective bypass paths. The phase compensation circuit is configured to compensate for an off-capacitance effect associated with the corresponding bypass path.

In some embodiments, some or all of the radio-frequency attenuator circuit can be implemented on a semiconductor die. In some embodiments, substantially all of the radio-frequency attenuator circuit can be implemented on the semiconductor die.

In some embodiments, the radio-frequency module can be configured to process a received radio-frequency signal. The radio-frequency module can be, for example, a diversity receive module.

In some embodiments, the radio-frequency module can further include a controller in communication with the radio-frequency attenuator circuit and configured to provide a control signal for operation of the radio-frequency attenuator circuit. The controller can be configured to provide, for example, a Mobile Industry Processor Interface control signal.

In accordance with some implementations, the present disclosure relates to a wireless device that includes an antenna configured to receive a radio-frequency signal, a transceiver in communication with the antenna, and a signal path between the antenna and the transceiver. The wireless device further includes a radio-frequency attenuator circuit implemented along the signal path. The attenuator circuit includes a plurality of attenuation blocks arranged in series between an input node and an output node, with each of the plurality of attenuation blocks including a bypass path. The attenuator circuit further includes a phase compensation circuit implemented for each of at least some of the attenuation blocks having the respective bypass paths. The phase compensation circuit is configured to compensate for an off-capacitance effect associated with the corresponding bypass path.

In some embodiments, the wireless device can further include a controller in communication with the radio-frequency attenuator circuit and configured to provide a control signal for operation of the radio-frequency attenuator circuit. The controller can be configured to provide, for example, a Mobile Industry Processor Interface control signal.

In some implementations, the present disclosure relates to a signal attenuator circuit that includes a plurality of local binary-weighted attenuation blocks arranged in series between an input node and an output node, with each attenuation block including a local bypass path. The signal attenuator circuit can further include a global bypass path implemented between the input node and the output node, and a local phase compensation circuit associated with at least one of the one or more local attenuation blocks. The local phase compensation circuit is configured to compensate for an off-capacitance effect associated with the respective local bypass path.

In some embodiments, the signal attenuator circuit can further include a global phase compensation circuit configured to compensate for an off-capacitance effect associated with the global bypass path.

In some implementations, the present disclosure relates to a semiconductor die that includes a semiconductor substrate, and a signal attenuator circuit implemented on the semiconductor substrate. The signal attenuator circuit includes a plurality of local binary-weighted attenuation blocks arranged in series between an input node and an output node, with each attenuation block including a local bypass path. The signal attenuator circuit further includes a global bypass path implemented between the input node and the output node, and a local phase compensation circuit associated with at least one of the one or more local attenuation blocks. The local phase compensation circuit is configured to compensate for an off-capacitance effect associated with the respective local bypass path.

In some implementations, the present disclosure relates to a radio-frequency module that includes a packaging substrate configured to receive a plurality of components, and a signal attenuator circuit implemented on the packaging substrate. The signal attenuator circuit further includes a plurality of local binary-weighted attenuation blocks arranged in series between an input node and an output node, with each attenuation block including a local bypass path. The signal attenuator circuit further includes a global bypass path implemented between the input node and the output node, and a local phase compensation circuit associated at least one of the one or more local attenuation blocks. The local phase compensation circuit is configured to compensate for an off-capacitance effect associated with the respective local bypass path.

In some implementations, the present disclosure relates to a wireless device that includes an antenna configured to receive a radio-frequency signal, a transceiver in communication with the antenna, and a signal path between the antenna and the transceiver. The wireless device further includes a signal attenuator circuit implemented along the signal path, and includes a plurality of local binary-weighted attenuation blocks arranged in series between an input node and an output node, with each attenuation block including a local bypass path. The signal attenuator circuit further includes a global bypass path implemented between the input node and the output node, and a local phase compensation circuit associated with at least one of the one or more local attenuation blocks. The local phase compensation circuit is configured to compensate for an off-capacitance effect associated with the respective local bypass path.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts an attenuator circuit configured to receive a signal at an input node and generate an attenuated signal at an output node.

FIG. 2 shows a block diagram of an attenuation circuit having a plurality of attenuation blocks implemented in a binary-weighted configuration.

FIG. 3 shows an attenuation circuit that can be a more specific example of the attenuation circuit of FIG. 2.

FIG. 4 shows the fourth attenuation block of FIG. 3 by itself.

FIG. 5 shows a circuit representation of the example attenuation block of FIG. 4, in which the various switching transistors are represented as either off-capacitance(s) or on-resistance(s).

FIG. 6 shows an individual attenuation block that can represent each of the second and third attenuation blocks of FIG. 3.

FIG. 7 shows a circuit representation of the example attenuation block of FIG. 6, in which the various switching transistors are represented as either off-capacitance(s) or on-resistance(s).

FIG. 8A shows an operating mode for the attenuation circuit of FIG. 3, in which each attenuation block is being bypassed, to provide a total attenuation of approximately 0 dB.

FIG. 8B shows an operating mode for the attenuation circuit of FIG. 3, in which attenuation is being provided by the first attenuation block, and each of the second to fourth attenuation blocks is being bypassed, to provide a total attenuation of approximately 1 dB.

FIG. 8C shows an operating mode for the attenuation circuit of FIG. 3, in which attenuation is being provided by the second attenuation block, and each of the first, third and fourth attenuation blocks is being bypassed, to provide a total attenuation of approximately 2 dB.

FIG. 8D shows an operating mode for the attenuation circuit of FIG. 3, in which attenuation is being provided by each of the first and second attenuation blocks, and each of the third and fourth attenuation blocks is being bypassed, to provide a total attenuation of approximately 3 dB.

FIG. 8E shows an operating mode for the attenuation circuit of FIG. 3, in which attenuation is being provided by each of the second to fourth attenuation blocks, and the first attenuation block is being bypassed, to provide a total attenuation of approximately 14 dB.

FIG. 8F shows an operating mode for the attenuation circuit of FIG. 3, in which attenuation is being provided by each of the four attenuation blocks, to provide a total attenuation of approximately 15 dB.

FIG. 9A shows a compensation path that includes a local compensation capacitance.

FIG. 9B shows that in some embodiments, the capacitance of FIG. 9A can be implemented as a transistor device configured to provide a desired capacitance value.

FIG. 10 shows that in some embodiments, an attenuation circuit having one or more features as described herein can be controlled by a controller.

FIG. 11 shows that in some embodiments, some or all of an attenuation circuit having one or more features as described herein can be implemented on a semiconductor die.

FIG. 12 shows an example where some or all of an attenuation circuit having one or more features as described herein can be implemented on a packaged module, and such a packaged module can include a semiconductor die similar to the example of FIG. 11.

FIG. 13 shows another example where some or all of an attenuation circuit having one or more features as described herein can be implemented on a packaged module, and such a packaged module can include a plurality of semiconductor die.

FIG. 14 shows non-limiting examples of how an attenuator having one or more features as described herein can be implemented in a radio-frequency system.

FIG. 15 shows an example of a diversity receive module that includes an attenuator having one or more features as described herein.

FIG. 16 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

Disclosed herein are various examples of circuits, devices and methods related to attenuators that can be utilized in, for example, radio-frequency (RF) applications. Although various examples are described herein in the context of RF applications, it will be understood that such circuits, devices and methods related to attenuators can be utilized in other electronic applications.

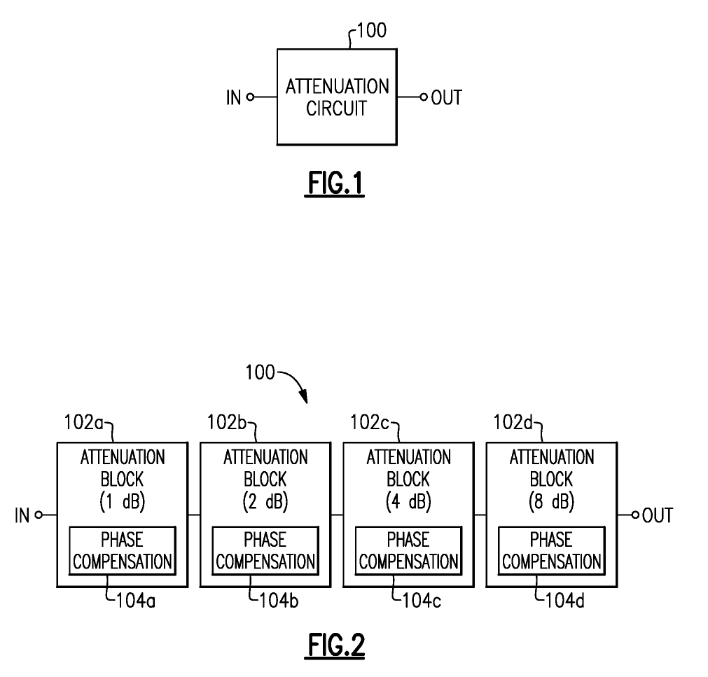

FIG. 1 depicts an attenuator circuit 100 configured to receive an RF signal at an input node (IN) and generate an attenuated RF signal at an output node (OUT). Such an attenuator circuit can include one or more features as described herein so as to provide desirable functionalities such as phase shift compensation, gain compensation, and/or low loss bypass capability. As described herein, such phase compensation can provide, for example, an approximately zero phase shift resulting from an attenuation block and/or the attenuator circuit itself. As also described herein, such gain compensation can provide, for example, an approximately flat gain over a frequency range.

It is noted that phase variation and gain slope are generally not desired when an input signal passes through an attenuator, since such effects can cause performance degradation in a communication link. In some embodiments, the attenuation circuit 100 of FIG. 1 can include a local compensation scheme to address the phase variation problem. In some embodiments, such an attenuation circuit can also include a global compensation scheme to address the phase variation problem. As described herein, such compensation schemes can be configured to address sources of such phase variations. As also described herein, such compensation schemes can also provide an approximately flat gain over a relatively wide frequency range. As also described herein, such compensation schemes can also provide a bypass path having relatively low loss which is desirable for keeping signal attenuation to a minimum under some situations (e.g., when an attenuation path is not being used).

For the purpose of description, an attenuation circuit can also be referred to as an attenuator assembly or simply an attenuator. Description of such an attenuation circuit, attenuator assembly, attenuator, etc. can apply to one or more attenuation blocks (also referred to herein as local attenuation), overall attenuation circuit (also referred to herein as global attenuation), or any combination thereof.

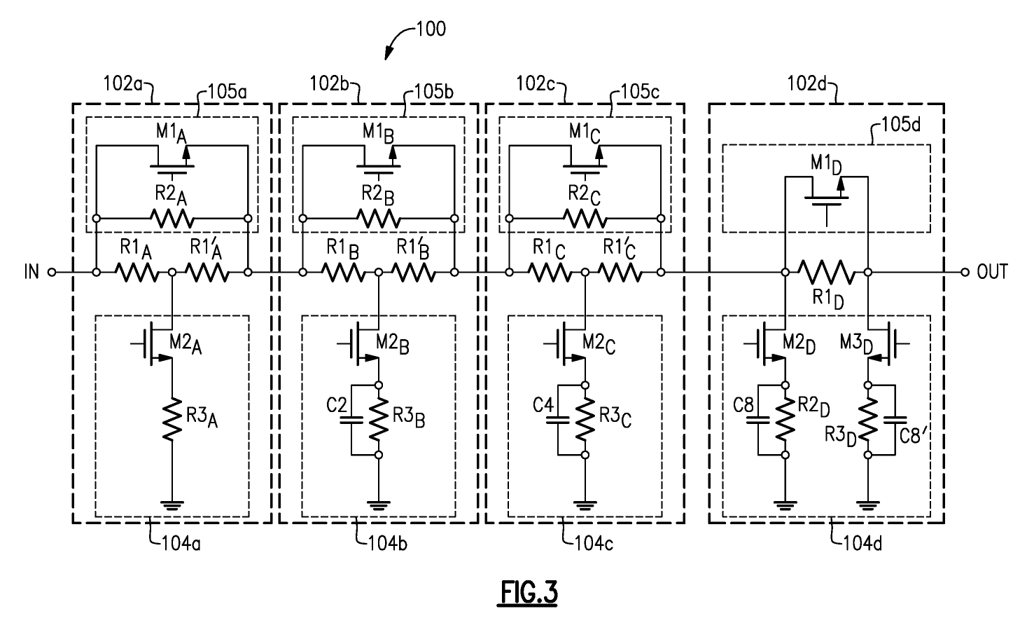

FIG. 2 shows a block diagram of an attenuation circuit 100 configured to receive an RF signal at its input node (IN) and provide an output RF signal at its output node (OUT). Such an output RF signal can be attenuated by one or more attenuation values, or be substantially the same as the input RF signal (e.g., through bypass functionality) when attenuation is not desired. Examples of how such attenuation values and bypass functionality can be implemented are described herein in greater detail. Also described herein are examples of how phase compensation can be implemented at a local attenuation level, at a global level, or any combination thereof.

In the example of FIG. 2, a plurality of attenuation blocks are shown to be implemented in a binary-weighted configuration. For example, four attenuation blocks (102a, 102b, 102c, 102d) are shown to be arranged in series between the input (IN) and output (OUT) nodes, and are shown to provide 1 dB, 2 dB, 4 dB, 8 dB attenuations, respectively. By different combinations of such attenuations (and/or bypasses), the attenuation circuit 100 can provide a total attenuation of 0 dB to 15 dB in 1 dB increments. Examples related to how such different total attenuations can be obtained are described herein in greater detail.

In the example of FIG. 2, as well as in other examples based on FIG. 2, four binary-weighted attenuation blocks are utilized. However, it will be understood that one or more features of the present disclosure can also be implemented in attenuation circuits having more or less numbers of attenuation blocks. For example, three attenuation blocks can be utilized to provide 0 dB to 7 dB attenuation values in 1 dB increments. In another example, five attenuation blocks can be utilized to provide 0 dB to 31 dB attenuation values in 1 dB increments.

In the various examples described herein, a step attenuation value is assumed to be 1 dB. However, it will be understood that such a step attenuation value can have a value other than 1 dB. Accordingly, it will be understood that one or more features of the present disclosure can be implemented in an attenuation circuit having a plurality of attenuation blocks capable of providing attenuation values based on a binary-weighted scheme where an i-th attenuation block is capable of providing an attenuation of A2ⁱ⁻¹, where A is a step attenuation value (e.g., 0.5 dB, 1 dB, 2 dB, etc.). For example, in the example of FIG. 2, A=1 dB, such that the first attenuation block (i=1) provides an attenuation of 1 dB×2°=1 dB; the second attenuation block (i=2) provides an attenuation of 1 dB×2¹=2 dB; and so on.

In another example, suppose that a finer granularity (e.g., 0.5 dB) in attenuation is desired for a similar range of attenuation as in the example of FIG. 2 (e.g. 0 to 15.5 dB). In such an example, a first attenuation block (i=1) can provide an attenuation of 0.5 dB×2⁰=0.5 dB, a second attenuation block (i=2) can provide an attenuation of 0.5 dB×2¹=1.0 dB, a third attenuation block (i=3) can provide an attenuation of 0.5 dB×2²=2.0 dB, a fourth attenuation block (i=4) can provide an attenuation of 0.5 dB×2³=4.0 dB, and a fifth attenuation block (i=5) can provide an attenuation of 0.5 dB×2⁴=8.0 dB. With such five binary-weighted attenuation blocks, attenuations values can be provided from 0 dB to 15.5 dB in 0.5 dB increments.

In the example of FIG. 2, each of the attenuation blocks 102a, 102b, 102c, 102d is shown to include a respective phase compensation circuit (104a, 104b, 104c, 104d). Examples related to such phase compensation circuits are described herein in greater detail. In the example of FIG. 2, all of the attenuation blocks are shown to have respective phase compensation circuits. However, it will be understood that in some embodiments, one or more attenuation blocks may or may not have such phase compensation circuit(s).

In the example of FIG. 2, it will be understood that the attenuation blocks 102a, 102b, 102c, 102d may or may not have similar attenuation configurations. For example, one or more of the attenuation blocks can have a T-attenuation configuration, and one or more of the attenuation blocks can have a pi-attenuation configuration. Thus, it will be understood that the attenuation circuit 100 of FIG. 2 can include one or more types of attenuation configurations among the attenuation blocks. It will also be understood that other types of attenuation configurations can be implemented in one or more attenuation blocks.

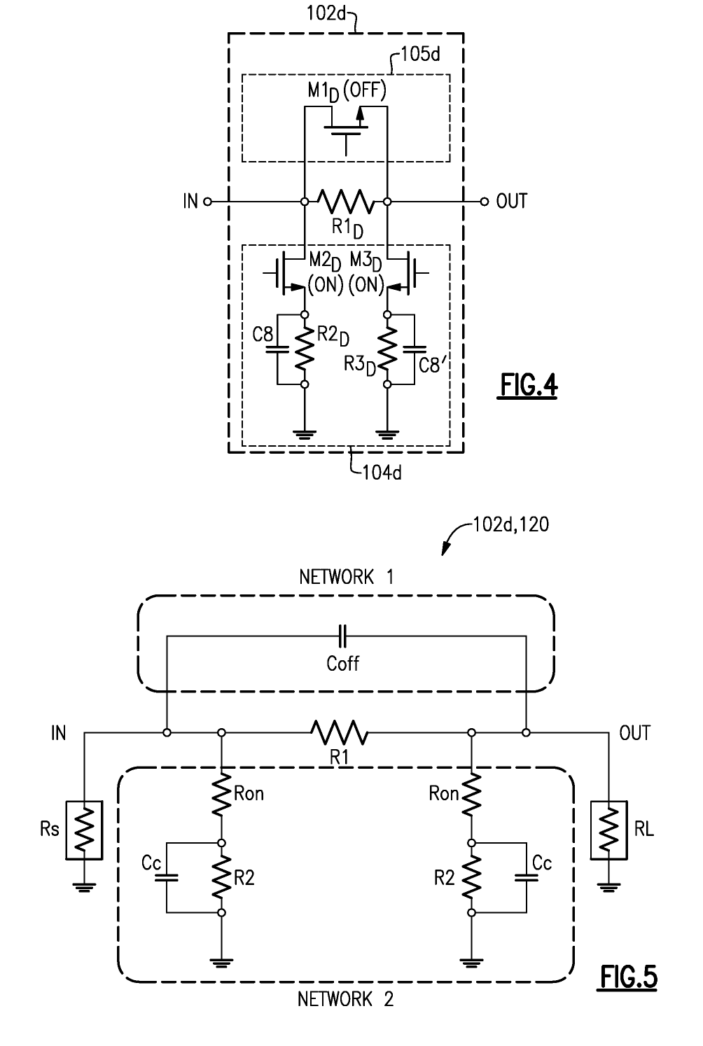

FIG. 3 shows an attenuation circuit 100 that can be a more specific example of the attenuation circuit 100 of FIG. 2. In the example of FIG. 3, each of three attenuation blocks 102a, 102b, 102c is shown to include a bridge-T-attenuator configuration and a corresponding bypass path (105a, 105b or 105c). For example, the first attenuation block 102a is shown to include resistances R1_{A}, R1′_{A}, R2_{A}, R3_{A} arranged in a bridge-T-configuration. The resistances R1_{A} and R1′_{A} are shown to be in series and implemented between input and output nodes of the first attenuation block 102a. The resistance R2_{A} is shown to be implemented between the input node and the output node so as to be electrically parallel with the series combination of R1_{A} and R1′_{A}. The resistance R3_{A} is shown to be implemented between ground and a node between R1_{A} and R1′_{A} (also referred to herein as a T-node).

Similarly, the second attenuation block 102b is shown to include resistances R1_{B}, R1′_{B}, R2_{B}, R3_{B} arranged in a bridge-T-configuration. The resistances R1_{B} and R1′_{B} are shown to be in series and implemented between input and output nodes of the first attenuation block 102b. The resistance R2_{B} is shown to be implemented between the input node and the output node so as to be electrically parallel with the series combination of R1_{B} and R1′_{B}. The resistance R3_{B} is shown to be implemented between ground and a node between R1_{B} and R1′_{B} (also referred to herein as a T-node).

Similarly, the third attenuation block 102c is shown to include resistances R1_{C}, R1′_{C}, R2_{C}, R3_{C} arranged in a bridge-T-configuration. The resistances R1_{C} and R1′_{C} are shown to be in series and implemented between input and output nodes of the first attenuation block 102c. The resistance R2_{C} is shown to be implemented between the input node and the output node so as to be electrically parallel with the series combination of R1_{C} and R1′_{C}. The resistance R3_{C} is shown to be implemented between ground and a node between R1_{C} and R1′_{C} (also referred to herein as a T-node).

In the example of FIG. 3, the fourth attenuation block 102d is shown to include resistances R1_{D}, R2_{D}, R3_{D} arranged in a pi-configuration. The resistance R1_{D} is shown to be implemented between input and output nodes of the fourth attenuation block 102d. The resistance R2_{D} is shown to be implemented between the input node and ground; similarly, the resistance R3_{D} is shown to be implemented between the output node and ground.

In the bridge-T-configuration of each of the three attenuation blocks 102a, 102b, 102c of FIG. 3, a switching FET (M2_{A}, M2_{B} or M2_{C}) can be provided between the corresponding T-node and one end of the shunt resistance (R3_{A}, R3_{B} or R3_{C}), with the other end of the shunt resistance being coupled to ground. Such a switching FET (M2_{A}, M2_{B} or M2_{C}) can be turned ON when attenuation is enabled for the corresponding attenuation block, and be turned OFF when attenuation is bypassed through the corresponding bypass path (105a, 105b or 105_{C}). Such a bypass path can include, for example, a corresponding switching FET (M1_{A}, M1_{B} or M1_{C}) which can be turned OFF when attenuation is enabled for the corresponding attenuation block, and be turned ON when attenuation is bypassed through the bypass path.

In the pi-configuration of the fourth attenuation block 102d of FIG. 3, a switching FET M2_{D} can be provided between the input node and one end of the resistance R2_{D}, with the other end of the resistance R2_{D} being coupled to ground. Similarly, a switching FET M3_{D} can be provided between the output node and one end of the resistance R3_{D}, with the other end of the resistance R3_{D} being coupled to ground. Such switching FETs (M2_{D} and M3_{D}) can be turned ON when attenuation is enabled for the fourth attenuation block 102d, and be turned OFF when attenuation is bypassed through the bypass path 105d. Such a bypass path (105d) can include, for example, a switching FET M1_{D} which can be turned OFF when attenuation is enabled for the fourth attenuation block 102d, and be turned ON when attenuation is bypassed through the bypass path 105d.

In the bridge-T-configuration of the second attenuation block 102b of FIG. 3, a capacitance C2 can be provided so as to be electrically parallel with the resistance R3_{B}. As described herein, such a capacitance can be selected to compensate for phase-shifting that occurs when an RF signal is passed through the attenuation block. As also described herein, such a capacitance can also allow the attenuation block to provide a desirably flat gain profile over a relatively wide frequency range.

Similarly, in the bridge-T-configuration of the third attenuation block 102c of FIG. 3, a capacitance C4 can be provided so as to be electrically parallel with the resistance R3_{C}. As described herein, such a capacitance can be selected to compensate for phase-shifting that occurs when an RF signal is passed through the attenuation block. As also described herein, such a capacitance can also allow the attenuation block to provide a desirably flat gain profile over a relatively wide frequency range.

In the pi-configuration of the fourth attenuation block 102d of FIG. 3, a capacitance C8 can be provided so as to be electrically parallel with the resistance R2_{D}. Similarly, a capacitance C8′ can be provided so as to be electrically parallel with the resistance R3_{D}. As described herein, such capacitances can be selected to compensate for phase-shifting that occurs when an RF signal is passed through the attenuation block. As also described herein, such capacitances can also allow the attenuation block to provide a desirably flat gain profile over a relatively wide frequency range.

In the example of FIG. 3, it is noted that the first attenuation block 102a does not include a compensation capacitance. In some embodiments, an attenuation block having a lower attenuation value may not result in a significant amount of phase shift; accordingly, a compensation circuit (e.g., a compensation capacitance) may or may not provide significant compensation benefit.

In the attenuation block 102b, the presence of the capacitance C2 in parallel with the resistance R3_{B} allows phase compensation to be implemented as described herein. As also described herein, such phase compensation can also depend on the values of one or more resistances associated with the attenuation block 102b, as well as on-resistance value (Ron) of the switching transistor M2_{B}. Accordingly, it will be understood that a box indicated as 104b can include some or all of circuit elements of a respective phase compensation circuit, or includes some or all of circuit elements that can influence such phase compensation.

Similarly, in the attenuation block 102c, the presence of the capacitance C4 in parallel with the resistance R3_{C} allows phase compensation to be implemented as described herein. As also described herein, such phase compensation can also depend on the values of one or more resistances associated with the attenuation block 102c, as well as on-resistance value (Ron) of the switching transistor M2_{C}. Accordingly, it will be understood that a box indicated as 104c can include some or all of circuit elements of a respective phase compensation circuit, or includes some or all of circuit elements that can influence such phase compensation.

In the attenuation block 102d, the presence of the capacitances C8 and C8′ in parallel with their respective resistances R2_{D} and R3_{D} allows phase compensation as described herein. As also described herein, such phase compensation can also depend on values of the resistances R2_{D} and R3_{D}, as well as on-resistance values (Ron) of the switching transistors M2_{D} and M3_{D}. Accordingly, it will be understood that a box indicated as 104d includes some or all of circuit elements of a phase compensation circuit, or includes some or all of circuit elements that can influence such phase compensation.

In the example of FIG. 3, some or all of the various switching FETs can be implemented as, for example, silicon-on-insulator (SOI) devices. It will be understood that while such various switching FETs are depicted as being NFETs, one or more features of the present disclosure can also be implemented utilizing other types of FETs. It will also be understood that the various switches in the example of FIG. 3 can also be implemented as other types of transistors, including non-FET transistors.

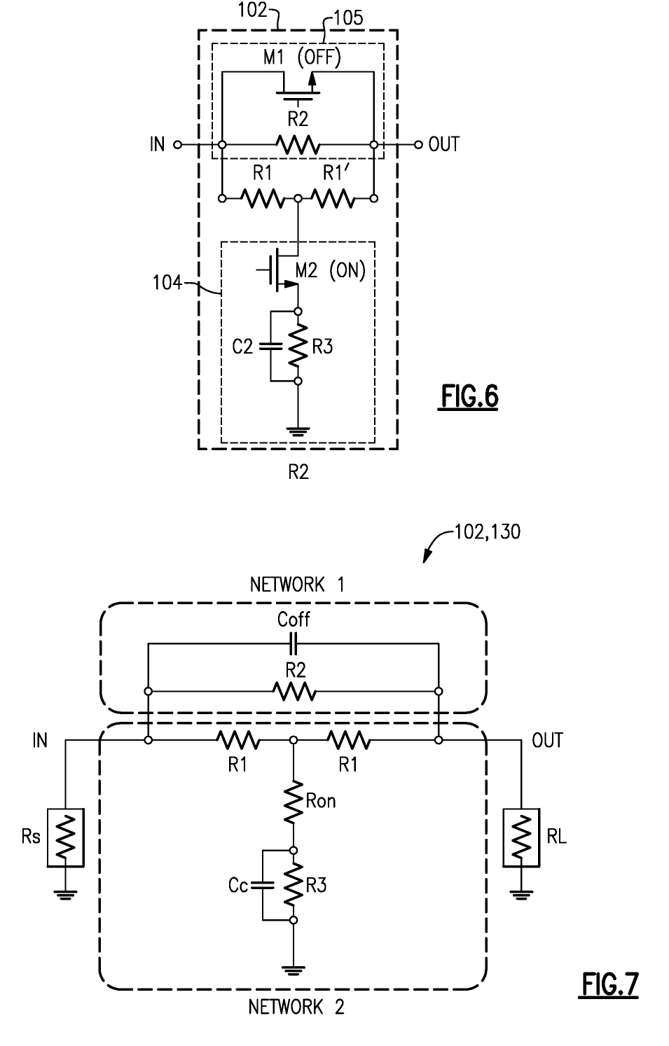

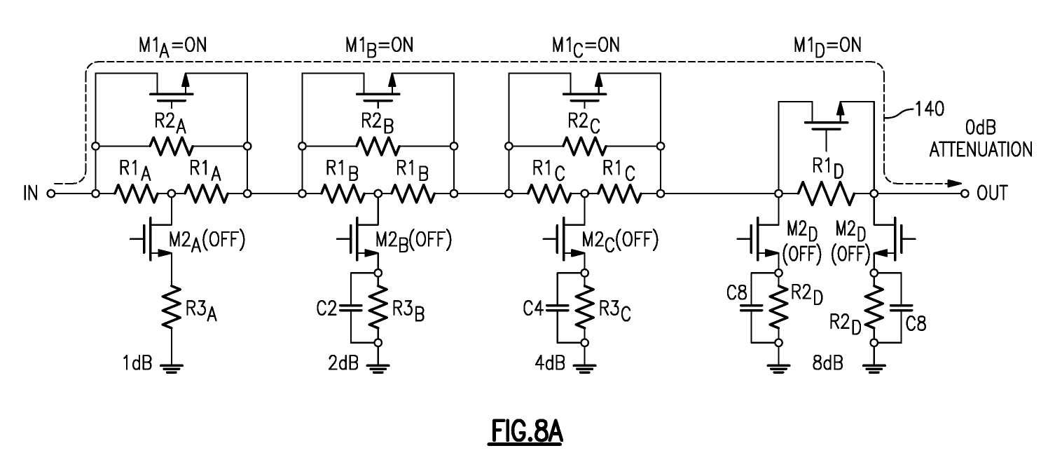

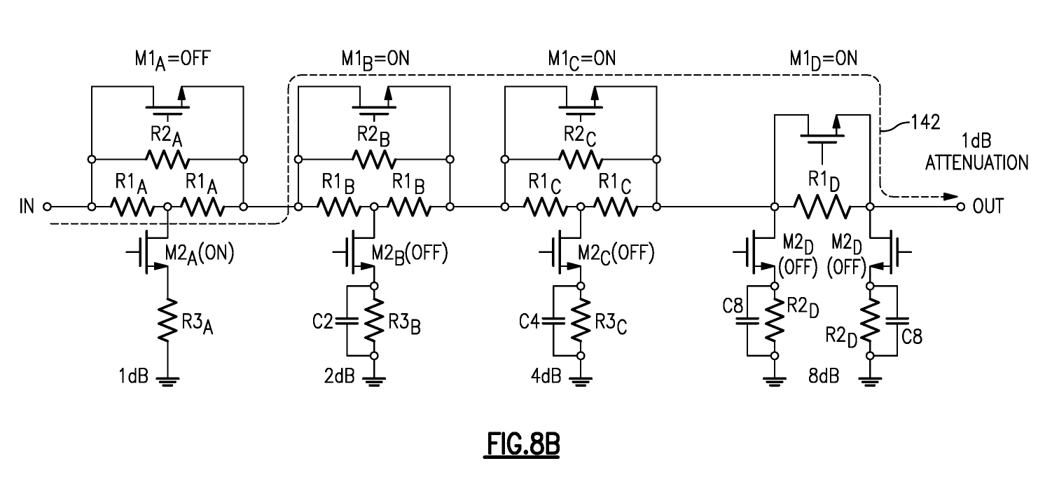

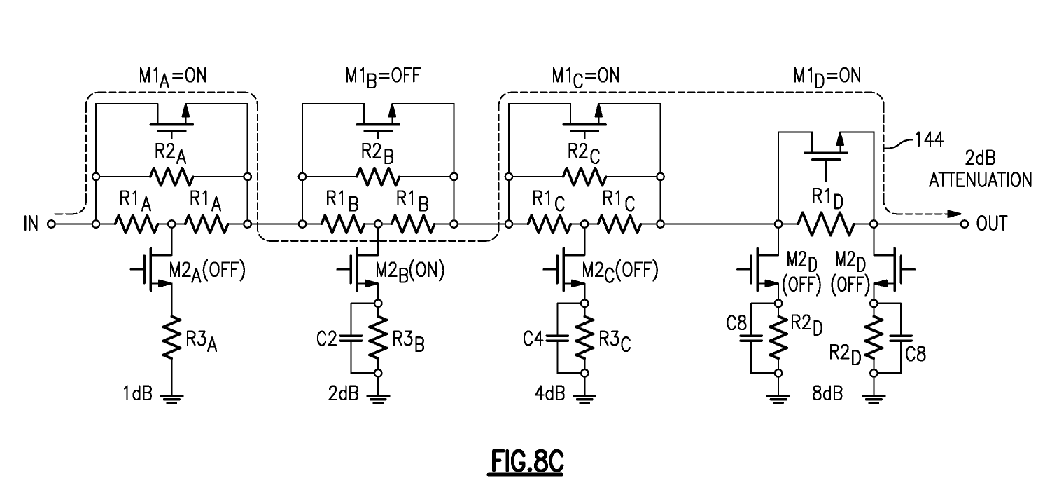

FIGS. 4 and 5 show an example of how phase compensation can be implemented for the attenuation block 102d of the example of FIG. 3. FIGS. 6 and 7 show an example of how phase compensation can be implemented for each of the attenuation blocks 102b, 102c of the example of FIG. 3.

FIG. 4 shows the attenuation block 102d by itself, and such an attenuation block can represent the fourth attenuation block 102d of FIG. 3. In the example of FIG. 4, the attenuation block 102d is in its attenuation mode, such that an RF signal received at the local input node (IN) is attenuated and provided at the local output node (OUT). Accordingly, the bypass switching FET M1_{D} of the bypass path 105d is OFF, and each of the switching FETs M2_{D} and M3_{D} of the circuit 104d is ON.

FIG. 5 shows a circuit representation 120 of the example attenuation block 102d of FIG. 4, in which the various switching FETs are represented as either off-capacitance(s) or on-resistance(s). For example, the OFF state of M1_{D} is represented as an off-capacitance Coff, and the ON state of each of M2_{D} and M3_{D} is represented as an on-resistance Ron. For the purpose of description, it is assumed that the pi-attenuator configuration of FIG. 4 is generally symmetric. Accordingly, M2_{D} can be similar to M3_{D}, such that Ron of M2_{D} is approximately the same as Ron of M3_{D}; hence, FIG. 5 depicts each of M2_{D} and M3_{D} as Ron. Similarly, the resistances R2_{D} and R3_{D} in FIG. 4 are assumed to be approximately the same; hence, FIG. 5 depicts each of R2_{D} and R3_{D} as having a resistance R2. Similarly, the capacitances C8 and C8′ in FIG. 4 are assumed to be approximately the same; hence, FIG. 5 depicts each of C8 and C8′ as having a compensation capacitance of Cc.

In FIG. 5, the circuit representation 120 is shown to have a source impedance Rs at the local input (IN), and a load impedance RL at the local output (OUT). Such impedance values may or may not be the same. For the purpose of description, however, values of Rs and RL are assumed to be the same at a characteristic impedance Z0 (e.g., at 50Ω).

With the foregoing assumption, values of R1 and R2 in the example of FIG. 5 can be obtained as follows:

$$\begin{matrix}{R}_{1} = \frac{{Z}_{0}}{2} \cdot \frac{K - 1}{K + 1} & ( 1 ) \\ {R}_{2} = {Z}_{0} \cdot \frac{K + 1}{K - 1} . & ( 2 )\end{matrix}$$

In Equations 1 and 2, the parameter K represents the attenuation value of the attenuation block 120. It is noted that as attenuation becomes larger, R1 generally increases, and R2 generally decreases.

Referring to FIG. 5, and assuming that the on-resistance Ron of each of M2_{D} and M3_{D} is approximately zero, a portion of the attenuation block 120, indicated as Network 1, can contribute to forward gain and phase shift (e.g., phase lead) of the attenuation block 120 as:

$$\begin{matrix}\frac{{V}_{out}}{{V}_{i n}} = \frac{{R}_{L} ( 1 + {sR}_{1} {C}_{off} )}{( {R}_{L} + {R}_{1} ) + {sR}_{L} {R}_{1} {C}_{off}} & ( 3 ) \\ φ = {tan}^{- 1} ( ω {R}_{1} {C}_{off} ) - {tan}^{- 1} ( ω \frac{{R}_{1} {R}_{L}}{{R}_{1} + {R}_{L}} {C}_{off} ) . & ( 4 )\end{matrix}$$

In FIG. 5, a portion of the attenuation block 120, indicated as Network 2, can contribute to forward gain and phase shift (e.g., phase lag) of the attenuation block 120 as:

$$\begin{matrix}\frac{{V}_{out}}{{V}_{i n}} = \frac{{R}_{2}^{′}}{( {R}_{2}^{′} + {R}_{1} ) + {sR}_{2}^{′} {R}_{1} {C}_{c}} & ( 5 ) \\ φ = - {tan}^{- 1} ( \frac{ω {R}_{1} {R}_{2}^{′} {C}_{c}}{{R}_{1} + {R}_{2}^{′}} ) . & ( 6 )\end{matrix}$$

In Equations 3-6, ω=2πf, where f is frequency, and R₂′ is a resistance value of parallel arrangement of R₂ and R_{L}.

Referring to FIGS. 4 and 5, and Equations 4 and 6, it is noted that the parameters ω, R_{L}, C_{off}, R₁ and R₂ are typically set for a given frequency, characteristic impedance, switching FET configuration, and attenuation value. However, in some embodiments, the value of the compensation capacitance Cc can be adjusted such that the phase lag of Equation 6 compensates for the phase lead of Equation 4. Such phase compensation can allow the phase associated with the attenuation block 102d/120 of FIGS. 4 and 5 to be at or near a desired value. For example, the compensated phase associated with the attenuation block 102d/120 can have substantially the same phase variation as in a reference mode.

Referring to FIGS. 4 and 5, it is noted that since Coff is in parallel arrangement with R1, its impedance 1/(jωC_{off}) will make an equivalent series impedance between the input and output nodes become smaller as frequency increases, resulting in less attenuation at a higher frequency. Inversely, higher attenuation can result at a lower frequency.

It is further noted that the compensation capacitance Cc is arranged parallel to the corresponding shunt resistance R2. Thus, the impedance (1/(jωC_{c})) of the compensation capacitance Cc will make an equivalent impedance of the shunt arm become less, resulting in more attenuation for the attenuation block. Thus, in some embodiments, the compensation capacitance Cc can be selected to compensate for the impact of Coff on gain, and thereby achieve a desired gain profile (e.g., approximately flat profile) for the attenuation block over a wide frequency range. In some embodiments, the compensation capacitance Cc can be selected to provide at least some phase compensation described herein, as well as to provide at least some gain compensation as described herein, for the attenuation block.

FIGS. 6 and 7 show an example of how phase compensation can be implemented for each of the attenuation blocks 102b, 102c of the example of FIG. 3. FIG. 6 shows an individual attenuation block 102, and such an attenuation block can represent each of the two example attenuation blocks 102b, 102c of FIG. 3. Accordingly, reference numerals of the various elements of the attenuation block 102 are shown without subscripts.

In the example of FIG. 6, the attenuation block 102 is in its attenuation mode, such that an RF signal received at the local input node (IN) is attenuated and provided at the local output node (OUT). Accordingly, the bypass switching FET M1 of the bypass path 105 is OFF, and the switching FET M2 of the circuit 104 is ON.

FIG. 7 shows a circuit representation 130 of the example attenuation block 102 of FIG. 6, in which the various switching FETs are represented as either off-capacitance(s) or on-resistance(s). For example, the OFF state of M1 is represented as an off-capacitance Coff, and the ON state of M2 is represented as an on-resistance Ron. For the purpose of description, it is assumed that the bridge-T-attenuator configuration of FIG. 6 is generally symmetric. Accordingly, the resistances R1 and R1′ in FIG. 6 are assumed to be approximately the same; hence, FIG. 7 depicts each of R1 and R1′ as having a resistance R1. In FIG. 7 the capacitance C2 of FIG. 6 is assumed as having a compensation capacitance of Cc.

In FIG. 7, the circuit representation 130 is shown to have a source impedance Rs at the local input (IN), and a load impedance RL at the local output (OUT). Such impedance values may or may not be the same. For the purpose of description, however, values of Rs and RL are assumed to be the same at a characteristic impedance Z0 (e.g., at 50Ω). Further, the resistance R1 can be assumed to have the same characteristic impedance Z0 (e.g., at 50Ω).

With the foregoing assumption, values of R2 and R3 in the example of FIG. 7 can be obtained as follows:

$$\begin{matrix}{R}_{2} = {R}_{1} \cdot ( K - 1 ) & ( 7 ) \\ {R}_{3} = \frac{{R}_{1}}{K - 1} . & ( 8 )\end{matrix}$$

In Equations 7 and 8, the parameter K represents the attenuation value of the attenuation block 130. It is noted that as attenuation becomes larger, R2 generally increases, and R3 generally decreases.

Referring to FIG. 7, and assuming that the on-resistance Ron of M2 is approximately zero, a portion of the attenuation block 130, indicated as Network 1, can contribute to forward gain and phase shift (e.g., phase lead) of the attenuation block 130 as:

$$\begin{matrix}\frac{{V}_{out}}{{V}_{i n}} = \frac{1 + {sR}_{2} {C}_{off}}{( 1 + \frac{{R}_{2}}{{R}_{L}} ) + {sR}_{2} {C}_{off}} & ( 9 ) \\ φ = {tan}^{- 1} ( ω {R}_{2} {C}_{off} ) - {tan}^{- 1} ( \frac{ω {R}_{2} {C}_{off}}{1 + \frac{{R}_{2}}{{R}_{L}}} ) . & ( 10 )\end{matrix}$$

In FIG. 7, a portion of the attenuation block 130, indicated as Network 2, can contribute to forward gain and phase shift (e.g., phase lag) of the attenuation block 130 as:

$$\begin{matrix}\frac{{V}_{out}}{{V}_{i n}} = \frac{0.5 \cdot {R}_{3}^{′}}{( {R}_{3}^{′} + {R}_{1} ) + {sR}_{3}^{′} {R}_{1} {C}_{c}} & ( 11 ) \\ φ = - {tan}^{- 1} ( \frac{ω {R}_{1} {R}_{3}^{′} {C}_{c}}{{R}_{1} + {R}_{3}^{′}} ) . & ( 12 )\end{matrix}$$

In Equations 9-12, ω=2πf, where f is frequency, and R₃′ is a resistance value of parallel arrangement of R₃ and (R₁+R_{L}).

Referring to FIGS. 6 and 7, and Equations 10 and 12, it is noted that the parameters ω, R_{L}, C_{off}, R₁, R₂ and R₃ are typically set for a given frequency, characteristic impedance, switching FET configuration, and attenuation value. However, in some embodiments, the value of the compensation capacitance Cc can be adjusted such that the phase lag of Equation 12 compensates for the phase lead of Equation 12. Such phase compensation can allow the phase associated with the attenuation block 102/130 of FIGS. 6 and 7 to be at or near a desired value. For example, the compensated phase associated with the attenuation block 102/130 can have substantially the same phase variation as in a reference mode.

Referring to FIGS. 6 and 7, it is noted that since Coff is in parallel arrangement with R2, its impedance 1/(jωC_{off}) will make an equivalent series impedance between the input and output nodes become smaller as frequency increases, resulting in less attenuation at a higher frequency. Inversely, higher attenuation can result at a lower frequency.

It is further noted that the compensation capacitance Cc is arranged parallel to the corresponding shunt resistance R3. Thus, the impedance (1/(jωC_{c})) of the compensation capacitance Cc will make an equivalent impedance of the shunt arm become less, resulting in more attenuation for the attenuation block. Thus, in some embodiments, the compensation capacitance Cc can be selected to compensate for the impact of Coff on gain, and thereby achieve a desired gain profile (e.g., approximately flat profile) for the attenuation block over a wide frequency range. In some embodiments, the compensation capacitance Cc can be selected to provide at least some phase compensation described herein, as well as to provide at least some gain compensation as described herein, for the attenuation block.

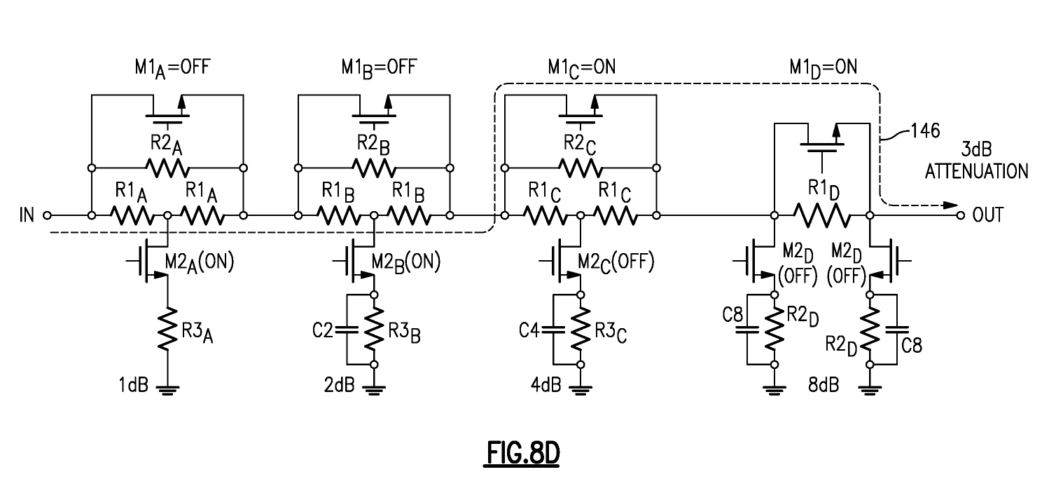

FIGS. 8A-8F show examples of different operating modes that can be implemented for the attenuation circuit 100 of FIG. 3. In FIG. 8A, the attenuation circuit 100 is shown to be in an overall bypass mode, such that the attenuation circuit 100 provides a total of approximately 0 dB attenuation. In such a mode, each of the bypass switches M1_{A}, M1_{B}, M1_{C}, M1_{D} is ON, and each of the shunt switches M2_{A}, M2_{B}, M2_{C}, M2_{D} (assuming M2_{D} is substantially the same as M3_{D} in FIG. 3) is OFF. Accordingly, an RF signal is shown to be routed as indicated by path 140. In such a mode, the RF signal is generally not subjected to a Coff capacitance; thus, undesirable phase shifting generally does not occur.

In FIG. 8B, the attenuation circuit 100 is shown to be in a mode to provide a total of approximately 1 dB attenuation. In such a mode, the bypass switch M1_{A} is OFF, and each of the remaining bypass switches M1_{B}, M1_{C}, M1_{D} is ON. Further, the shunt switch M2_{A} is ON, and each of the remaining shunt switches M2_{B}, M2_{C}, M2_{D} is OFF. Accordingly, an RF signal is shown to be routed as indicated by path 142. In such a mode, the RF signal is generally subjected to only a Coff capacitance of the bypass switch M1_{A}; and as described herein, such a mode may or may not need phase compensation.

In FIG. 8C, the attenuation circuit 100 is shown to be in a mode to provide a total of approximately 2 dB attenuation. In such a mode, the bypass switch M1_{B} is OFF, and each of the remaining bypass switches M1_{A}, M1_{C}, M1_{D} is ON. Further, the shunt switch M2_{B} is ON, and each of the remaining shunt switches M2_{A}, M2_{C}, M2_{D} is OFF. Accordingly, an RF signal is shown to be routed as indicated by path 144. In such a mode, the RF signal is generally subjected to a Coff capacitance of the bypass switch M1_{B}; and as described herein, phase compensation can be implemented by providing an appropriate value for the capacitance C2.

In FIG. 8D, the attenuation circuit 100 is shown to be in a mode to provide a total of approximately 3 dB attenuation. In such a mode, each of the bypass switches M1_{A}, M1_{B} is OFF, and each of the remaining bypass switches M1_{C}, M1_{D} is ON. Further, each of the shunt switches M2_{A}, M2_{B} is ON, and each of the remaining shunt switches M2_{C}, M2_{D} is OFF. Accordingly, an RF signal is shown to be routed as indicated by path 146. In such a mode, the RF signal is generally subjected to a Coff capacitance of each of the bypass switches M1_{A}, M113, and as described herein, phase compensation can be implemented by providing an appropriate value for the capacitance C2.

Higher attenuation values can be provided in similar manners by incrementing in 1 dB steps by different combinations of the binary-weighted attenuation blocks. Continuing such increase in attenuation, a total attenuation of approximately 14 dB can be provided by the attenuation circuit 100, as shown in FIG. 8E. In such a mode, each of the bypass switches M1_{B}, M1_{C}, M1_{D} is OFF, and the remaining bypass switch M1_{A} is ON. Further, each of the shunt switches M2_{B}, M2_{C}, M2_{D} is ON, and the remaining shunt switch M2_{A} is OFF. Accordingly, an RF signal is shown to be routed as indicated by path 148. In such a mode, the RF signal is generally subjected to a Coff capacitance of each of the bypass switches M1_{B}, M1_{C}, M1_{D}, and as described herein, phase compensation can be implemented by providing appropriate values for the capacitances C2, C4, C8.

As shown in FIG. 8F, a total attenuation of approximately 15 dB can be provided by the attenuation circuit 100. In such a mode, each of the bypass switches M1_{A}, M1_{B}, M1_{C}, M1_{D} is OFF, and each of the shunt switches M2_{A}, M2_{B}, M2_{C}, M2_{D} is ON. Accordingly, an RF signal is shown to be routed as indicated by path 150. In such a mode, the RF signal is generally subjected to a Coff capacitance of each of the bypass switches M1_{A}, M1_{B}, M1_{C}, M1_{D}, and as described herein, phase compensation can be implemented by providing appropriate values for the capacitances C2, C4, C8.

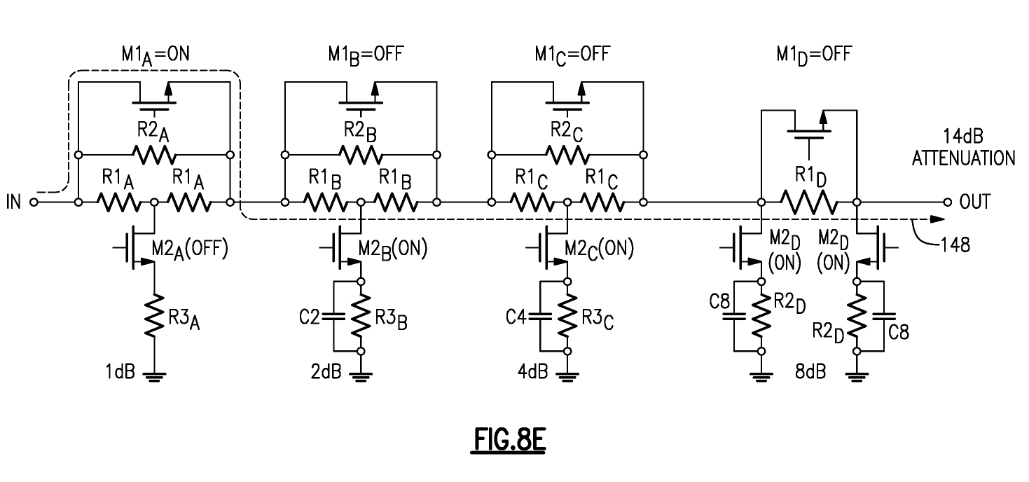

As described herein, a compensation circuit (e.g., 104b, 104c, 104c in FIG. 3) can include a compensation capacitance (e.g., C2, C4, C8 in FIG. 3, and Cc in FIGS. 5 and 7). FIG. 9A shows a compensation path 170 that includes such a local compensation capacitance (indicated as C). Such a compensation path is also shown to have a resistance R in parallel with C.

FIG. 9B shows that in some embodiments, the capacitance C of FIG. 9A can be implemented as a FET device 172 (e.g., as a MOSFET device) configured to provide a desired capacitance value of C. For example, source and drain of the FET device 172 can be connected to the two ends of the resistance R, and a gate of the FET device 172 can be grounded without a gate bias, such that the FET device 172 acts as a capacitance similar to that of C of FIG. 9A.

When the compensation capacitance is implemented as in the example of FIG. 9B, a number of desirable features can be achieved. For example, the compensation capacitance elements can be fabricated essentially together with the various FETs (e.g., bypass FETs M1_{B}, M1_{C}, M1_{D} in FIG. 3). In another example, and assuming the foregoing fabrication process commonality, the FET devices 172 acting as capacitances are affected by essentially the same process variations that affect the other FETS (including the local bypass FETs M1_{B}, M1_{C}, M1_{D}). Accordingly, process independence can be achieved among, for example, the FET devices 172 and the other FETs.

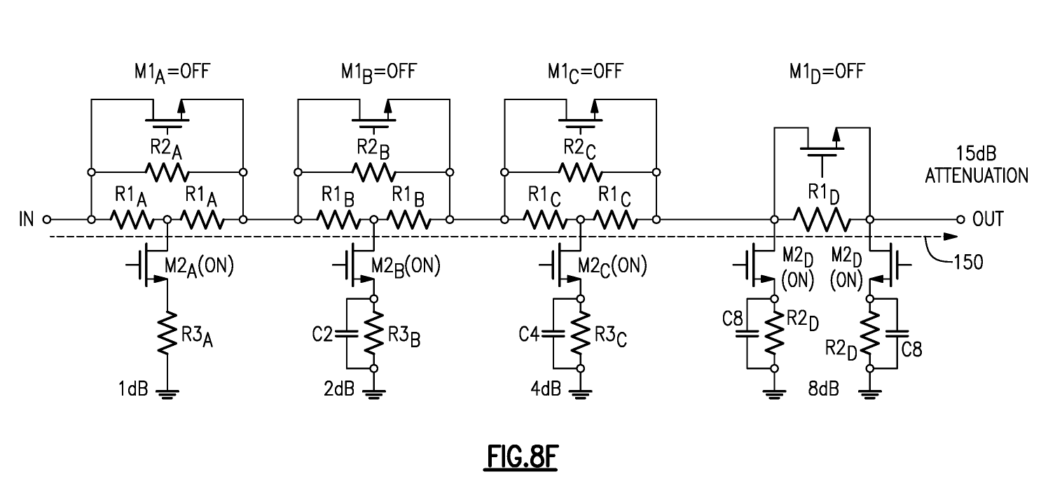

FIG. 10 shows that in some embodiments, an attenuation circuit 100 having one or more features as described herein can further include a global bypass path 106 and a global phase compensation circuit 108. Such a global bypass path can be activated by allowing an RF signal received at the input node (IN) to be routed to the output node (OUT) through the global bypass path 106. In such a global bypass mode, each of a first switch S1 between the input node and a first node 110 and a second switch S2 between a second node and the output node can be opened to generally isolate the binary weighted attenuation blocks (collectively indicated as 102) and one or more local phase compensation circuits therein (collectively indicated as 104).

When the attenuation circuit 100 is in an attenuation mode, the binary-weighted attenuation blocks 102 and their local phase compensation circuit(s) 104 therein can be operated as described herein, and the global bypass path 106 can be disabled. Thus, an RF signal received at the input node (IN) can be routed to the output node (OUT) through the closed first switch S1, the binary-weighted attenuation blocks 102, and the closed second switch S2. In such an attenuation mode, some or all of phase shift (e.g., phase lead) associated with the disabled global bypass path 106 can be compensated by the global phase compensation circuit 108. Additional details concerning such global bypass path and global phase compensation are described in U.S. patent application Ser. No. ______ [Attorney Docket 75900-50336US], entitled ATTENUATORS HAVING PHASE SHIFT AND GAIN COMPENSATION CIRCUITS, the disclosure of which is filed on even date herewith and hereby incorporated by reference herein in its entirety and to be considered part of the specification of the present application.

FIG. 10 further shows that in some embodiments, an attenuation circuit 100 having one or more features as described herein can be controlled by a controller 180. Such a controller can provide various control signals to, for example, operate the various switches to achieve various attenuation modes (e.g., as in FIGS. 8A-8F). In some embodiments, the controller 180 can be configured to include MIPI (Mobile Industry Processor Interface) functionality.

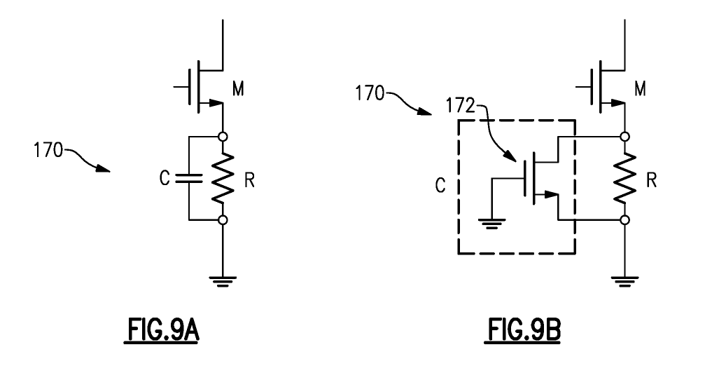

FIG. 11 shows that in some embodiments, some or all of an attenuation circuit 100 having one or more features as described herein can be implemented on a semiconductor die 200. Such a die can include a substrate 202, and at least some of a phase/gain compensation circuit 204 (e.g., phase compensation circuits 104a, 104b, 104c, 104d of FIG. 3) can be implemented on the substrate 202. For example, some or all of compensation capacitances C2, C4, C8, C8′ can be implemented as on-die capacitors.

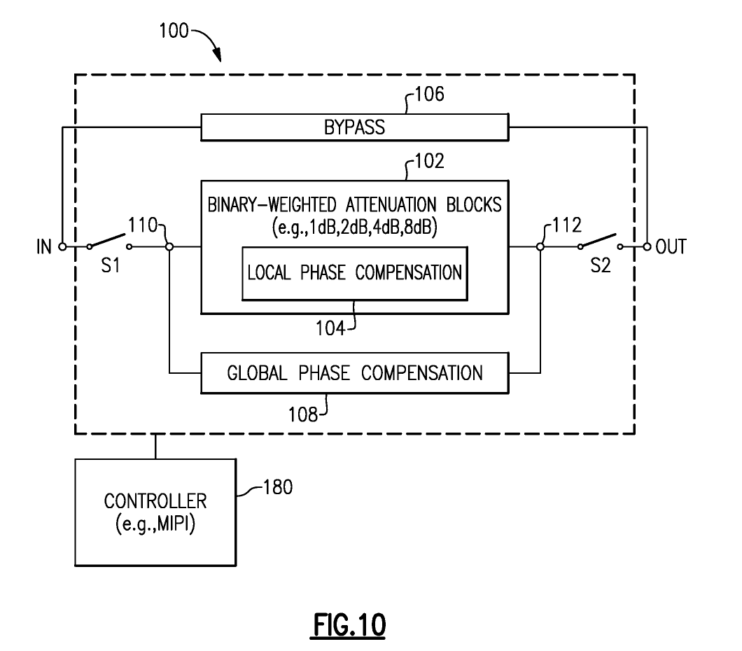

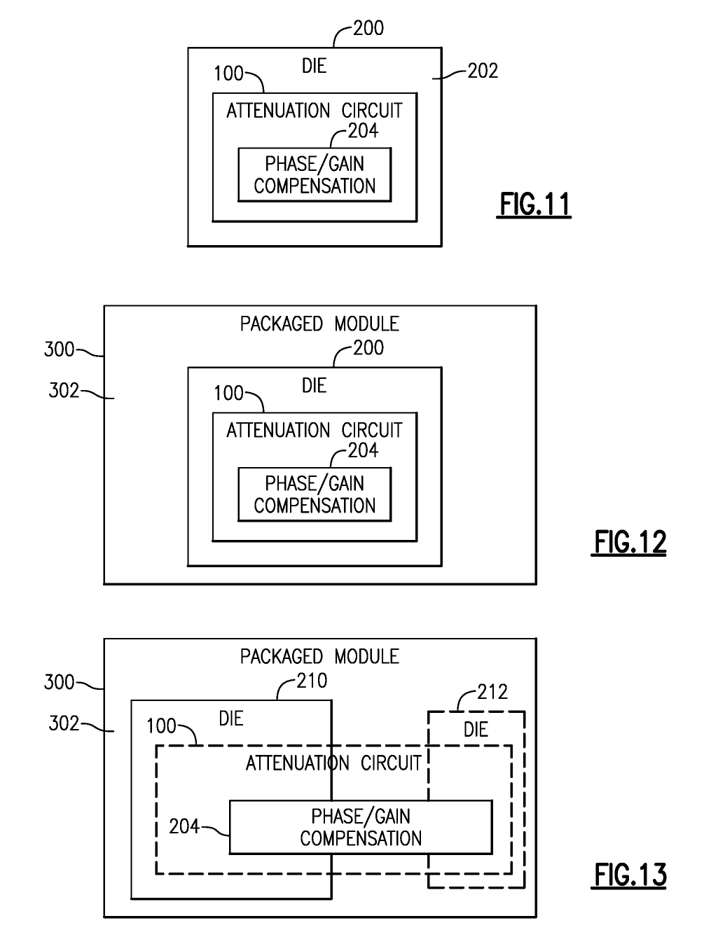

FIGS. 12 and 13 show that in some embodiments, some or all of an attenuation circuit 100 having one or more features as described herein can be implemented on a packaged module 300. Such a module can include a packaging substrate 302 configured to receive a plurality of components such as one or more die and one or more passive components.

FIG. 12 shows that in some embodiments, the packaged module 300 can include a semiconductor die 200 that is similar to the example of FIG. 11. Accordingly, such a die can include some or all of the attenuation circuit 100, with at least some of a phase/gain compensation circuit 204 (e.g., phase compensation circuits 104a, 104b, 104c, 104d of FIG. 3) being implemented on the die 200.

FIG. 13 shows that in some embodiments, the packaged module 300 can include a first semiconductor die 210 having some of the attenuation circuit 100, while the rest of the attenuation circuit 100 is implemented on another die 212, outside of a die (e.g., on the packaging substrate 302), or any combination thereof. In such a configuration, some of a phase/gain compensation circuit 204 (e.g., phase compensation circuits 104a, 104b, 104c, 104d of FIG. 3) can be implemented on the first die 210, and the rest of the phase/gain compensation circuit 204 can be implemented on another die 212, outside of a die (e.g., on the packaging substrate 302), or any combination thereof.

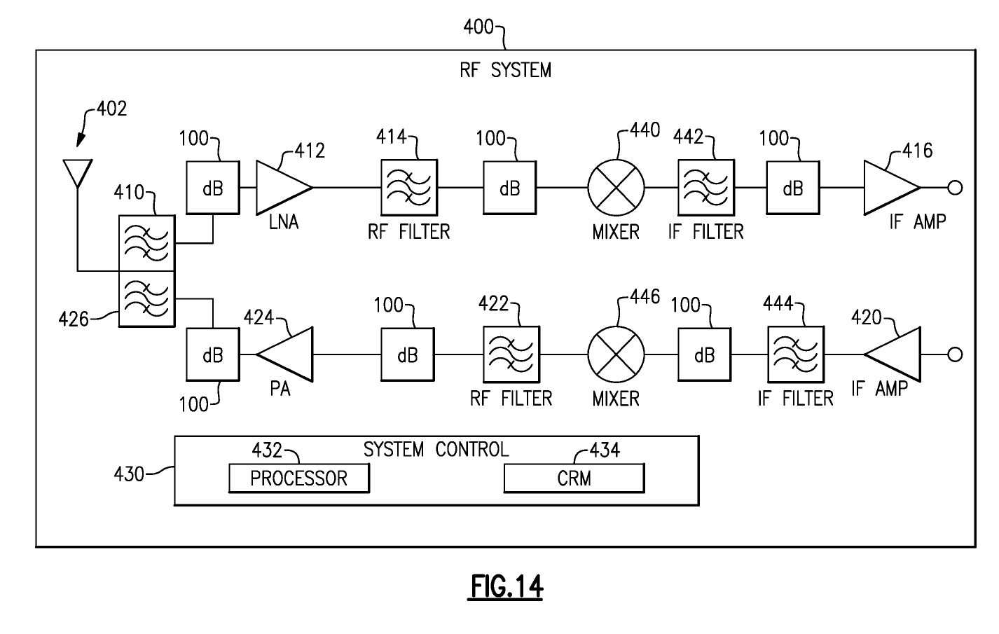

FIG. 14 shows non-limiting examples of how an attenuator having one or more features as described herein can be implemented in an RF system 400. Such an RF system can include an antenna 402 configured to facilitate reception and/or transmission of RF signals. In the context of reception, an RF signal received by the antenna 402 can be filtered (e.g., by a band-pass filter 410) and passed through an attenuator 100 before being amplified by a low-noise amplifier (LNA) 412. Such an LNA-amplified RF signal can be filtered (e.g., by a band-pass filter 414), passed through an attenuator 100, and routed to a mixer 440. The mixer 440 can operate with an oscillator (not shown) to yield an intermediate-frequency (IF) signal. Such an IF signal can be filtered (e.g., by a band-pass filter 442) and passed through an attenuator 100 before being routed to an intermediate-frequency (IF) amplifier 416. Some or all of the foregoing attenuators 100 along the receive path can include one or more features as described herein.

In the context of transmission, an IF signal can be provided to an IF amplifier 420. An output of the IF amplifier 420 can be filtered (e.g., by a band-pass filter 444) and passed through an attenuator 100 before being routed to a mixer 446. The mixer 446 can operate with an oscillator (not shown) to yield an RF signal. Such an RF signal can be filtered (e.g., by a band-pass filter 422) and passed through an attenuator 100 before being routed to a power amplifier (PA) 424. The PA-amplified RF signal can be routed to the antenna 402 through an attenuator 100 and a filter (e.g., a band-pass filter 426) for transmission. Some or all of the foregoing attenuators 100 along the transmit path can include one or more features as described herein.

In some embodiments, various operations associated with the RF system 400 can be controlled and/or facilitated by a system controller 430. Such a system controller can include, for example, a processor 432 and a storage medium such as a non-transient computer-readable medium (CRM) 434. In some embodiments, at least some control functionalities associated with the operation of one or more attenuators 100 in the RF system 400 can be performed by the system controller 430.

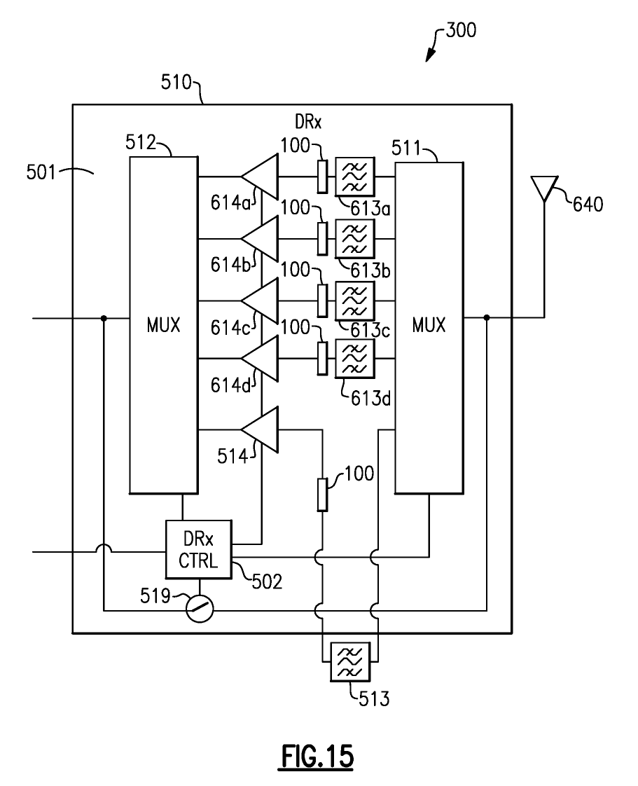

In some embodiments, an attenuation circuit having one or more features as described herein can be implemented along a receive (Rx) chain. For example, a diversity receive (DRx) module can be implemented such that processing of a received signal can be achieved close to a diversity antenna. FIG. 15 shows an example of such a DRx module.

In FIG. 15, a diversity receiver module 300 can be an example of the modules 300 of FIGS. 12 and 13. In some embodiments, such a DRx module can be coupled to an off-module filter 513. The DRx module 300 can include a packaging substrate 501 configured to receive a plurality of components and a receiving system implemented on the packaging substrate 501. The DRx module 300 can include one or more signal paths that are routed off the DRx module 300 and made available to a system integrator, designer, or manufacturer to support a filter for any desired band.

The DRx module 300 of FIG. 15 is shown to include a number of paths between the input and the output of the DRx module 300. The DRx module 300 is also shown to include a bypass path between the input and the output activated by a bypass switch 519 controlled by the DRx controller 502. Although FIG. 15 depicts a single bypass switch 519, in some implementations, the bypass switch 519 may include multiple switches (e.g., a first switch disposed physically close to the input and a second switch disposed physically close to the output. As shown in FIG. 15, the bypass path does not include a filter or an amplifier.

The DRx module 300 is shown to include a number of multiplexer paths including a first multiplexer 511 and a second multiplexer 512. The multiplexer paths include a number of on-module paths that include the first multiplexer 511, a bandpass filter 613a-613d implemented on the packaging substrate 501, an amplifier 614a-614d implemented on the packaging substrate 501, and the second multiplexer 512. The multiplexer paths include one or more off-module paths that include the first multiplexer 511, a bandpass filter 513 implemented off the packaging substrate 501, an amplifier 514, and the second multiplexer 512. The amplifier 514 may be a wide-band amplifier implemented on the packaging substrate 501 or may also be implemented off the packaging substrate 501. In some embodiments, the amplifiers 614a-614d, 514 may be variable-gain amplifiers and/or variable-current amplifiers.

A DRx controller 502 can be configured to selectively activate one or more of the plurality of paths between the input and the output. In some implementations, the DRx controller 502 can be configured to selectively activate one or more of the plurality of paths based on a band select signal received by the DRx controller 502 (e.g., from a communications controller). The DRx controller 502 may selectively activate the paths by, for example, opening or closing the bypass switch 519, enabling or disabling the amplifiers 614a-614d, 514, controlling the multiplexers 511, 512, or through other mechanisms. For example, the DRx controller 502 may open or close switches along the paths (e.g., between the filters 613a-613d, 513 and the amplifiers 614a-614d, 514) or by setting the gain of the amplifiers 614a-614d, 514 to substantially zero.

In the example DRx module 300 of FIG. 15, some or all of the amplifiers 614a-614d, 514 can be provided with an attenuation circuit 100 having one or more features as described herein. For example, each of such amplifiers is shown to have an attenuation circuit 100 implemented on its input side. In some embodiments, a given amplifier can have an attenuation circuit on its input side and/or on its output side.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

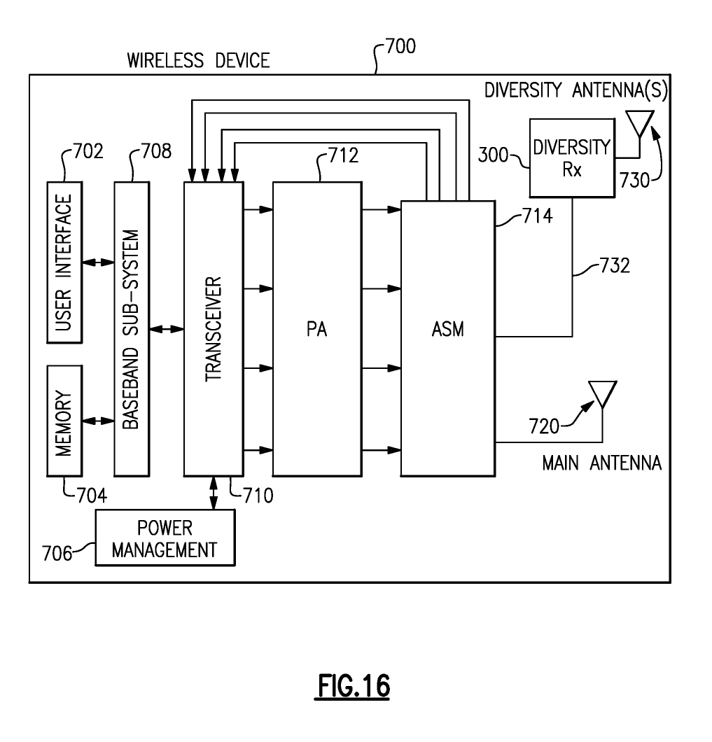

FIG. 16 depicts an example wireless device 700 having one or more advantageous features described herein. As described in reference to FIGS. 14 and 15, one or more attenuators having one or more features as described herein can be implemented in a number of places in such a wireless device. For example, in some embodiments, such advantageous features can be implemented in a module such as a diversity receive (DRx) module 300 having one or more low-noise amplifiers (LNAs). Such a DRx module can be configured as described herein in reference to FIGS. 12, 13 and 15. In some embodiments, an attenuator having one or more features as described herein can be implemented along an RF signal path before and/or after an LNA.

In the example of FIG. 16, power amplifiers (PAs) in a PA module 712 can receive their respective RF signals from a transceiver 710 that can be configured and operated to generate RF signals to be amplified and transmitted, and to process received signals. The transceiver 710 is shown to interact with a baseband sub-system 708 that is configured to provide conversion between data and/or voice signals suitable for a user and RF signals suitable for the transceiver 710. The transceiver 710 is also shown to be connected to a power management component 706 that is configured to manage power for the operation of the wireless device 700. Such power management can also control operations of the baseband sub-system 708 and other components of the wireless device 700.

The baseband sub-system 708 is shown to be connected to a user interface 702 to facilitate various input and output of voice and/or data provided to and received from the user. The baseband sub-system 708 can also be connected to a memory 704 that is configured to store data and/or instructions to facilitate the operation of the wireless device, and/or to provide storage of information for the user.

In the example of FIG. 16, the DRx module 300 can be implemented between one or more diversity antennas (e.g., diversity antenna 730) and the ASM 714. Such a configuration can allow an RF signal received through the diversity antenna 730 to be processed (in some embodiments, including amplification by an LNA) with little or no loss of and/or little or no addition of noise to the RF signal from the diversity antenna 730. Such processed signal from the DRx module 300 can then be routed to the ASM through one or more signal paths.

In the example of FIG. 16, a main antenna 720 can be configured to, for example, facilitate transmission of RF signals from the PA module 712. In some embodiments, receive operations can also be achieved through the main antenna.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio-frequency attenuator circuit comprising:
a plurality of attenuation blocks arranged in series between an input node and an output node, each of the plurality of attenuation blocks including a bypass path; and
a phase compensation circuit implemented for each of at least some of the attenuation blocks having the respective bypass paths, the phase compensation circuit configured to compensate for an off-capacitance effect associated with the corresponding bypass path.

2. The attenuator circuit of claim 1 wherein the attenuation blocks have binary-weighted attenuation values.

3. (canceled)

4. (canceled)

5. (canceled)

6. (canceled)

7. (canceled)

8. The attenuator circuit of claim 1 wherein at least one of the attenuation blocks is configured as a pi-attenuator.

9. The attenuator circuit of claim 8 wherein the at least one attenuation block having the pi-attenuator includes an attenuation block having a highest attenuation value.

10. The attenuator circuit of claim 8 wherein the bypass path of the attenuation block having the pi-attenuator includes a bypass switching transistor configured to be on when the attenuation block is in a bypass mode and off when in an attenuation mode, such that the bypass switching transistor provides an off-capacitance when in the attenuation mode.

11. The attenuator circuit of claim 10 wherein the phase compensation circuit of the attenuation block having the pi-attenuator includes a phase compensation circuit configured to compensate for the off-capacitance when the attenuator block is in the attenuation mode.

12. The attenuator circuit of claim 11 wherein the pi-attenuator includes a resistance, a first shunt path implemented between one end of the resistance and a ground, a second shunt path implemented between the other end of the resistance and the ground, each of the first and second shunt paths including a shunt resistance.

13. The attenuator circuit of claim 12 wherein the phase compensation circuit associated with the pi-attenuator includes a first compensation capacitance arranged to be electrically parallel with the first shunt resistance, and a second compensation capacitance arranged to be electrically parallel with the second shunt resistance.

14. The attenuator circuit of claim 13 wherein the off-capacitance of the bypass switching transistor results in a phase lead change, and the phase compensation circuit is configured to provide a phase lag change to compensate for the phase lead change.

15. (canceled)

16. (canceled)

17. (canceled)

18. (canceled)

19. The attenuator circuit of claim 1 wherein at least one of the attenuation blocks is configured as a bridge-T-attenuator.

20. The attenuator circuit of claim 19 wherein the bypass path of the attenuation block having the bridge-T-attenuator includes a bypass switching transistor configured to be on when the attenuation block is in a bypass mode and off when in an attenuation mode, such that the bypass switching transistor provides an off-capacitance when in the attenuation mode.

21. The attenuator circuit of claim 20 wherein the phase compensation circuit of the attenuation block having the bridge-T-attenuator includes a phase compensation circuit configured to compensate for the off-capacitance when the attenuator block is in the attenuation mode.

22. The attenuator circuit of claim 21 wherein the bridge-T-attenuator includes two first resistances connected in series, a second resistance electrically parallel with the series combination of the two first resistances, and a shunt path implemented between a ground and a node between the two first resistances, the shunt path including a shunt resistance.

23. The attenuator circuit of claim 22 wherein the phase compensation circuit associated with the bridge-T-attenuator includes a compensation capacitance arranged to be electrically parallel with the shunt resistance.

24. The attenuator circuit of claim 23 wherein the off-capacitance of the bypass switching transistor results in a phase lead change, and the phase compensation circuit is configured to provide a phase lag change to compensate for the phase lead change.

25. (canceled)

26. (canceled)

27. (canceled)

28. The attenuator circuit of claim 1 further comprising a global bypass path that includes a global bypass switching transistor configured to be on when in a global bypass mode and off when in a global attenuation mode, such that the global bypass switching transistor provides a global off-capacitance when in the global attenuation mode.

29. The attenuator circuit of claim 28 further comprising a global phase compensation circuit configured to compensate for the global off-capacitance when the attenuator circuit is in the global attenuation mode.

30. The attenuator circuit of claim 29 wherein the global phase compensation circuit includes a first global compensation resistance and a second global compensation resistance arranged in series between the input node and the output node, the global phase compensation circuit further including a global compensation capacitance implemented between a ground and a node between the first and second global compensation resistances.

31. (canceled)

32. (canceled)

33. (canceled)

34. (canceled)

35. (canceled)

36. (canceled)

37. A radio-frequency module comprising:
a packaging substrate configured to receive a plurality of components; and
a radio-frequency attenuator circuit implemented on the packaging substrate, the attenuator circuit including a plurality of attenuation blocks arranged in series between an input node and an output node, each of the plurality of attenuation blocks including a bypass path, the attenuator circuit further including a phase compensation circuit implemented for each of at least some of the attenuation blocks having the respective bypass paths, the phase compensation circuit configured to compensate for an off-capacitance effect associated with the corresponding bypass path.

38. (canceled)

39. (canceled)

40. (canceled)

41. (canceled)

42. (canceled)

43. (canceled)

44. A wireless device comprising:
an antenna configured to receive a radio-frequency signal;
a transceiver in communication with the antenna;
a signal path between the antenna and the transceiver; and
a radio-frequency attenuator circuit implemented along the signal path, the attenuator circuit including a plurality of attenuation blocks arranged in series between an input node and an output node, each of the plurality of attenuation blocks including a bypass path, the attenuator circuit further including a phase compensation circuit implemented for each of at least some of the attenuation blocks having the respective bypass paths, the phase compensation circuit configured to compensate for an off-capacitance effect associated with the corresponding bypass path.

45-51. (canceled)
